(19) United States
(12) Patent Application Publication
(10) Pub. No.: US 2008/0265402 A1
(43) Pub. Date: Oct. 30, 2008

(54) REWORK PROCESS AND METHOD FOR LEAD-FREE CAPPED MULTI-CORE MODULES WITH ORGANIC SUBSTRATES

(75) Inventor: Arvind K. Sinha, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/741,840

(22) Filed: Apr. 30, 2007

(51) Int. Cl. H01L 23/10; H01L 21/54

(52) U.S. Cl. 257/702; 438/115; 257/E23.193; 257/E21.501

(57) ABSTRACT

A system and method for utilizing lead-free multi-core modules with organic substrates,including a base portion configured to attach a semiconductor chip;and a cap portion further comprising: a bottom portion configured to be sealed to the base portion;and a vacuum port;wherein when a vacuum is drawn at the vacuum port,a re-workable seal between the base portion and the cap portion is provided to enable rework.

### TRADEMARKS

IBM R is a registered trademark of Internationa; Business Machines Corporation, Armonk,New York,U.S.A. Other names used herein may be registered trademarks, trademarks or product names of International Business machines Corporation or other companies.

### BACKGROUND OF THE INVENTION

1. Field of the Invention

This invention relates to electronic circuit packaging,and particularly to a method of utilizing lead free capped multi-core modules with organic substrates.

2. Description of the Background

Organic laminate substrate materials include epoxy-glass (FR-4),polyimide- quartz,and PTFE (Teflon)-glass composites. The two Pb-Sn (lead-tin) solders currently used for Level 1 and Level 2 interconnections are eutectic 37Pb-63Sn and near eutectic 40Pb-60Sn compositions. A eutectic or eutectic mixture is a mixture of two or more phases at a composition that has the lowest melting point, and where the phases simultaneously crystallize from molten solution at this temperature. The liquidus temperatures of the solders allow for process conditions that are compatible with organic circuit board laminates and packaging molding compounds. The liquidus temperature is the temperature at which total melting of the solid is achieved upon heating from the solid state, or at which solid first appears upon cooling from the liquid state.

However,use of lead-free solders results in a temperature rise in excess of 40oC. This rise in liquidus temperature during Level 1 and Level 2 packaging has an adverse effect on thermal and mechanical reliability during processing and reflow conditions. Level 1 refers to wafer level packaging while level 2 refers to when the chip along with the substrate is attached to a card.

Current use of capped multi-core modules require use of two thermal interfaces and it is not possible to rework the thermal interface material between the silicon and the lid due to high shear and tensile force involved. Therefore, considering the above limitations, it is desired to have a method of utilizing lead free-capped multi-core modules with organic substrates.

### SUMMARY OF THE INVENTION

The shortcomings of the prior art are overcome and additional advantages are provided through the provision of a system comprising: a base portion configured to attach a semiconductor chip;and a cap portion further comprising; a bottom portion configured to be sealed to the base portion; and a vacuum port;wherein when a vacuum is drawn at the vacuum port, a re-workable seal between the base portion and the cap portion is provided to enable rework.

The shortcomings of the prior art are overcome and additional advantages are provided through the provision of a method comprising;attaching a semiconductor chip to a base portion;and providing a cap portion, the cap portion further comprsing:sealing to the base portion a bottom portion;and providing a vacuum port;wherein when a vacuum is drawn at the vacuum port,a re-workable seal between the base portion and the cap portion is provided to enable work.

Additional features and advantages are realized through the techniques of the present invention. Other embodiments and aspects of the invention are described in detail herein and are considered a part of the claimed invention. For a better understanding of the invention with advantages and features, refer to the description and the drawings.

### TECHNICAL EFFECTS

As a result of the summerized invention, technically we have achieved a solution for a method of utilizing lead free-capped multi-core modules with organic substrates.

### BRIEF DESCRIPTION OF THE DRAWINGS

The subject matter,which is regarded as the invention, is particularly pointed out and distinctly claimed in the claims at the conclusion of the specification. The foregoing and other objects,features,and advantages of the invention are apparent from the following detailed description taken in conjunction with the accompanying drawings in which:

FIG.1 is a flow diagram of a process for reworking a thermal interface material, in accordance with an embodiment of the invention;and

FIG.2 is a schematic diagram of a lid, in accordance with an embodiment of the invention.

### DETAILED DESCRIPTION OF THE INVENTION

One aspect of the exemplary embodiments is a method and a prototype for reworking a thermal interface material. In another exemplary embodiment,a stronger adhesion of TIM1 is provided with silicon due to a vacuum.In yet another exemplary wmbodiment,out-of-plane flatness of multi-core modules in increased,removal of a lid for rework is easily accomplished,and inexpensive cleaning and ashing processes are performed.

A traditional lidded Ball Grid Array (BGA) package requires use of thermal interface material,which has adequate thermal properties to dissipate heat away from the chip. As the heat output of the chip increases, a thin thermal interface bond line is required to provide an efficient thermal dissipation path.To achieve thin bond lines requires heat sink actuation loads to be increased, creating issues such as chip cracking, Thermal Interface Material (TIM) gap stability,solder degradation,and solder-board interface failures. The current process of attaching a lid to the chip makes no room for rework of the chip at a Level 1 packaging process.

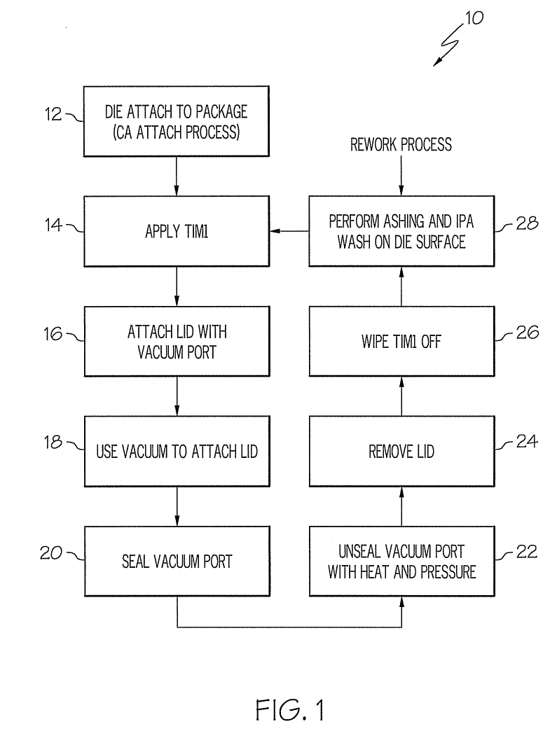

Referring to FIG. 1, a flow diagram of a process for reworking a thermal interface material, in accordance with an embodiment of the invention is illistrated.The process flow 10 includes the following steps. At step 12,the die is attached to a package. At step 14,the TIM1 is applied.TIM1 refers to the thermal interface material used in level 1 packaging, the material between the chip and the cap.It is the same as the regular TIM. At step 16,the lid is attached with the vacuum port.At step 18, the vacuum is used to attach the lid. At step 20,the vacuum port is sealed.At step 22,the vacuum port is unsealed with heat and pressure.At step 24,the lid is removed.At step 26, the TIM1 is wiped off.At step 28,ashing and IPA wash are performed on the die surface.IPA stands for isopropyl alcohol. It is used to at the top surface of the chip to reduce dust and oily residue,before dispensing with TIM.Ashing is the operation of removing resist from a substrate by oxidation.

The exemplary embodiments of the present invention involve using a specially designed lid with vacuum port.This lid is used to hold the TIM1 together and to increase overall adhesion by vacuum assistance,thus resulting in better flatness across the TIM1 interface. This is especially important because of the tolerance mismatch of the various die used in multi-core packages.Once the vacuum is applied the port is sealed with lead- free solder material. If rework is needed either due to TIM1 failure as indicated by an on- board chip temperature sensor or due to a defective module, the vacuum seal could be melted and the lid could be removed. This process requires use of a relatively high thermal conductive TIM1 with weak adhesion properties. As a result,the defective module or the TIM1 could be replaced. The die is then cleaned using plasma ashing process and debris removed by IPA wipe process. In semiconductor manufacturing plasma ashing is the process of removing the photoresist from an etched wafer. Using a plasma source, a monatomic reactive species is generated. Oxygen or fluorine are the most common reactive species. The reactive species combines with the photoresist to form ash which is removed with a vacuum pump. Once the surface of the die is clean,a new TIM1 can be applied and lid can be vacuum attached.

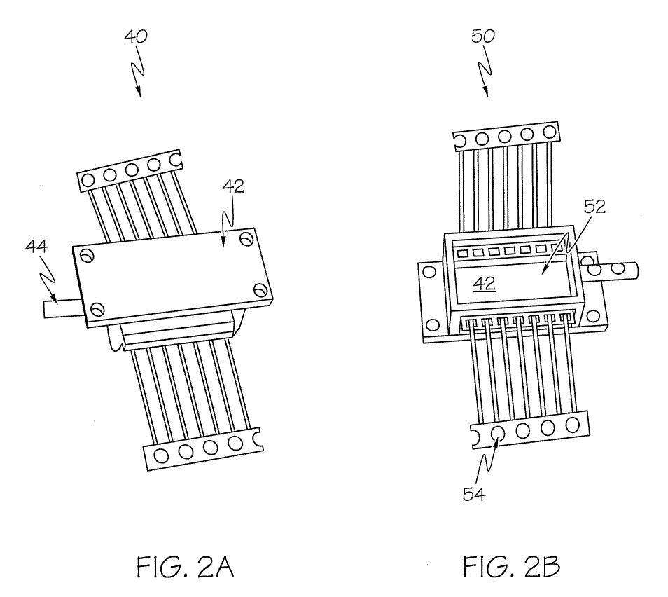

Reffering to Figure 2,a schematic diagram of a lid, in according with an embodiment of the invention,is illustrated.Elements 40 illustrates a top view of the lid and element 50 illustrates a bottom view of the lid. Referring to the top view 40,the copper lid 42 includes a vacuum port 44. Referring to the bottom view 50,the copper lid 42 includes a die placement area 52 and power and signal lines 54.

The capabilities of the present invention can be implemented in software, firmware, hardware or some combination thereof.

As one example,one or more aspects of the present invention can be included in an article of manufacture (e.g., one or more computer program products)having,for instance,computer usable media.The media has embodied therein,for instance, computer readable program code means for providing and facilitating the capabilities of the present invention. The article of manufacture can be included as a part of a computer system or sold seperatly.

While the preferred embodiment to the invention has been described, it will be understood that those skilled in the art, both now and in the future,may make various improvements and enhancements which fall within the scope of the claims which follow. These claims should be construed to maintain the proper protection for the invention first described.

What is claimed is:

1. A system for utilizing lead-free capped multi-core modules with organic substrates,the system comprising:
a base portion configured to attach a semiconductor chip;and
a cap portion further comprising:
a bottom portion configured to be sealed to the base portion;and
a vacuum port;
wherein when a vacuum is drawn at the vacuum port,a re-workable seal between the base portion and the cap portion is provided to enable rework.

2. The system of claim 1,wherein the rework is provided at a level 1 packaging.

3. A method for utilizing lead-free capped multi-core modules with organic substrates, the method comprising:
attaching a semiconductor chip to a base portion;and
providing a cap portion,the cap portion further comprising:
sealing to the base portion a bottom portion;and
providing a vacuum port;
wherein when a vacuum is drawn at the vacuum port, a re-workable seal between the base portion and the cap portion is provided to enable rework.

4. The method of claim 3,wherein the rework is provided at a level 1 packaging.

5. A method for utilizing lead-free capped multi-core modules with organic substrates, the method comprising:
attaching a die to a package;
applying a Thermal Interface Material (TIM);
attaching a lid with a vacuum port;
sealing the vacuum port;
unsealing the vacuum port with heat and pressure;
removing the lid;
wiping off the TIM;and
performing ashing and isopropyl alcohol wash on the die.
